(19) United States
(12) Patent Application Publication
(10) Pub. No.: US 2021/0118671 A1
(43) Pub. Date: Apr. 22, 2021

(54) ATOMIC LAYER DEPOSITION OF INDIUM GERMANIUM ZINC OXIDE

(71) Applicant: ASM IP Holding B.V., Almere (NL)

(72) Inventors: Oreste Madia, Leuven (BE); Andrea Illiberi, Leuven (BE); Giuseppe Alessio Verni, Antwerp (BE); Tatiana Ivanova, Espoo (FI); Perttu Sippola, Helsinki (FI); Michael Eugene Givens, Helsinki (FI)

(21) Appl. No.: 17/072,524

(22) Filed: Oct. 16, 2020

Related U.S. Application Data
(60) Provisional application No. 62/916,465, filed on Oct. 17, 2019.

(51) Int. Cl. H01L 21/02; C23C 16/455; C23C 16/40

(52) U.S. Cl. CPC H01L 21/0262; C23C 16/407; C23C 16/45553; H01L 21/02565

(57) ABSTRACT

Methods of forming indium germanium zinc oxide (IGeZO) films by vapor deposition are provided. The IGeZO films may, for example, serve as a channel layer in a transistor device. In some embodiments atomic layer deposition processes for depositing IGeZO films comprise an IGeZO deposition cycle comprising alternately and sequentially contacting a substrate in a reaction space with a vapor phase indium precursor, a vapor phase germanium precursor, a vapor phase zinc precursor and an oxygen reactant. In some embodiments the ALD deposition cycle additionally comprises contacting the substrate with an additional reactant comprising one or more of NH₃, N₂O, NO₂ and H₂O₂.

### REFERENCE TO RELATED APPLICATION

This application claims priority to U.S. Provisional Application No. 62/916,465, filed Oct. 17, 2019, which is incorporated by reference herein.

### BACKGROUND OF THE INVENTION

### Field of the Invention

The application relates to vapor deposition processes for forming indium germanium zinc oxide (IGeZO) films. In some aspects the IGeZO films are used in memory applications.

### Background

Amorphous oxide semiconductors (AOSs) have become the mainstream backplane technology in the display industry. Indium gallium zinc oxide (IGZO) is the most common AOS material. New applications of IGZO are emerging in the semiconductor industry, especially in logic and memory devices, and as channel material for V-NAND. IGZO is typically deposited by sputtering. There is a need for processes which enable depositing AOS films having desirable characteristics, such as a high mobility and stability with respect to post deposition treatments.

### BRIEF DESCRIPTION OF THE DRAWINGS

FIG. 1 is a flow chart illustrating an indium germanium zinc oxide (IGeZO) deposition cycle according to some embodiments.

### SUMMARY

In some aspects, methods of forming indium germanium zinc oxide (IGeZO) films by vapor deposition are provided. In some embodiments the methods may be atomic layer deposition (ALD) methods. The IGeZO may, for example, serve as a channel layer in a transistor device, such as a DRAM access transistor channel. In some embodiments the IGeZO film may be part of a back endo of line (BEOL) logic device. In some embodiments the IGeZO film may be part of a VNAND device.

In some embodiments atomic layer deposition (ALD) processes for depositing IGeZO films comprise an IGeZO deposition cycle comprising alternately and sequentially contacting a substrate in a reaction space with a vapor phase indium precursor, a vapor phase germanium precursor, a vapor phase zinc precursor and an oxygen reactant. The deposition cycle may be repeated until an IGeZO film of a desired thickness has been formed. In some embodiments, the deposition cycle is conducted at a deposition temperature of 250° C. or less.

In some embodiments the ALD deposition cycle additionally comprises contacting the substrate with an additional reactant comprising one or more of NH₃, N₂O, NO₂ and H₂O₂. In some embodiments the substrate is contacted simultaneously with the oxygen reactant and the additional reactant.

In some embodiments, the oxygen reactant comprises one or more of water, ozone and H₂O₂. in some embodiments the germanium precursor comprises at least one amine or alkylamine ligand. In some embodiments the germanium precursor comprises one or more of Ge(NMe₂)₃ (TDMAGe), Ge(NEt₂)₃ and Ge(NEtMe)₃. In some embodiments the zinc precursor comprises one or more of elemental zinc, a zinc halide, and an alkyl zinc compound. In some embodiments the zinc precursor comprises Zn(Et)₂ or Zn(Me). In some embodiments the indium precursor comprises one or more of an indium alkyl compound, an indium beta diketonate, an indium cyclopentadienyl and an indium halide. In some embodiments the indium precursor comprises one or more of trimethyl indium, In(acac), InCp, and an indium halide

In some embodiments, the indium precursor is trimethyl indium, the zinc precursor is diethyl zinc and the germanium precursor is TDMAGe.

In some embodiments, in the deposition cycle the substrate is contacted with the oxygen reactant after being contacted with the indium, zinc and germanium precursors.

In some embodiments, the IGeZO deposition cycle comprises an indium zinc oxide (IZO) sub-cycle and a germanium zinc oxide (GeZO) sub-cycle. In some embodiments the IGeZO film comprises a mixture of indium zinc oxide and germanium zinc oxide. The deposition cycle may be repeated N1 times, with the IZO sub-cycle repeated N2 times within the deposition cycle and the GeZO sub-cycle repeated N3 times within the deposition cycle, where N is an integer.

In some embodiments the IGeZO deposition cycle comprises an indium zinc oxide (IZO) sub-cycle and an indium germanium zinc oxide (IGeZO) sub-cycle. In some embodiments, the deposition cycle is repeated N1 times and the indium zinc oxide (IZO) sub-cycle is repeated N2 times within the deposition cycle and the indium germanium zinc oxide (IGeZO) sub-cycle is repeated N3 times within the deposition cycle, where N is an integer.

:In some embodiments, the IGeZO deposition cycle is repeated N1 times and comprises a zinc oxide sub-cycle that is repeated N2 times, the zinc oxide sub-cycle comprising alternately and sequentially contacting the substrate with the zinc precursor and the oxygen reactant, an indium oxide sub-cycle that is repeated N3 times, the indium oxide sub-cycle comprising alternately and sequentially contacting the substrate with the indium precursor and the oxygen reactant and a germanium oxide sub-cycle that is repeated N4 times, the germanium oxide sub-cycle comprising alternately and sequentially contacting the substrate with the germanium precursor and the oxygen reactant, wherein N is an integer. In some embodiments the indium precursor is trimethyl indium, the zinc precursor is diethyl zinc and the germanium precursor is TDMAGe.

In some embodiments, the IGeZO deposition cycle is repeated N1 times and comprises a zinc indium oxide sub-cycle that is repeated N2 times and comprises alternately and sequentially contacting the substrate with the zinc precursor, the indium precursor and the oxygen reactant and a germanium oxide sub-cycle that is repeated N3 times and comprises alternately and sequentially contacting the substrate with the germanium precursor and the oxygen reactant, where N is an integer.

In some embodiments, the IGeZO deposition cycle is repeated N1 times and comprises a zinc germanium oxide sub-cycle that is repeated N2 times and comprises alternately and sequentially contacting the substrate with the zinc precursor, the germanium precursor and the oxygen reactant; and an indium oxide sub-cycle that is repeated N3 times and comprises alternately and sequentially contacting the substrate with the indium precursor and the oxygen reactant, where N is an integer.

In some embodiments, the IGeZO deposition cycle is repeated N1 times and comprises a zinc oxide sub-cycle that is repeated N2 times and comprises alternately and sequentially contacting the substrate with the zinc precursor and the oxygen reactant; and an indium germanium oxide sub-cycle that is repeated N3 times and comprises alternately and sequentially contacting the substrate with the indium precursor and the germanium precursor and the oxygen reactant, where N is an integer.

In some embodiments, the IGeZO deposition cycle is repeated N1 times and comprises an indium zinc oxide (IZO) sub-cycle that is repeated N2 times and an indium germanium zinc oxide (IGeZO) sub-cycle that is repeated N3 times, where N is an integer. The IZO and IGeZO sub-cycles may be carried out at a predetermined ratio to deposit a film with the desired characteristics.

In some embodiments an ALD process for forming an IGeZ0thin film on a substrate in a reaction space comprises conducing a deposition cycle comprising alternately and sequentially contacting the substrate with a vapor phase indium precursor, a vapor phase germanium precursor, and a vapor phase zinc precursor. The deposition cycle additionally comprises contacting the substrate with a first oxygen reactant and a second reactant. The deposition cycle may be repeated two or more times until an IGeZO film of a desired thickness has been formed. In some embodiments the second reactant comprises one or more of NH₃ , N₂O, NO₂ and H₂O₂.

In some embodiments the substrate is contacted with the oxygen reactant after being contacted with at least one of the indium, germanium and zinc reactants. In some embodiments the substrate is contacted with the oxygen reactant after being contacted with each of the indium, germanium and zinc reactants. In some embodiments the substrate is contacted with the oxygen reactant and the second reactant simultaneously. In some embodiments the second reactant is provided to the reaction space continuously during the deposition cycle.

In some embodiments, a deposition cycle comprises alternately and sequentially contacting the substrate with a vapor phase indium precursor, a vapor phase germanium precursor, a vapor phase zinc precursor, the first oxygen reactant and the second reactant.

### DETAILED DESCRIPTION

Methods of depositing indium germanium zinc oxide (IGeZO) thin films by a vapor deposition process, such as atomic layer deposition, are provided. In some embodiments an IGeZO thin film is formed on a substrate by a vapor deposition process comprising alternately and sequentially exposing a substrate to a vapor phase indium precursor, a vapor phase germanium precursor, a vapor phase zinc precursor, and one or more oxygen reactants. As discussed below, in some embodiments a deposition cycle comprises one or more sub-cycles in which an oxide is deposited. For example, in some embodiments binary oxides of each precursor can be deposited in three deposition sub-cycles. In other embodiments, two or more precursors are provided prior to the oxygen reactant in a sub-cycle. For example, in some embodiments indium zinc oxide IZO is deposited in one sub-cycle by alternately and sequentially exposing the substrate to an indium precursor, a zinc precursor and an oxygen reactant, and germanium zinc oxide is deposited in a second sub-cycle by alternately and sequentially exposing the substrate to a germanium precursor, a zinc precursor and an oxygen reactant. In some embodiments, a single deposition cycle comprises exposing a substrate to each of a germanium precursor, a zinc precursor and an indium precursor and exposing the substrate to an oxygen reactant after exposure to the three precursors, where the three precursors can be provided in any order. In some embodiments an additional reactant gas, such as a gas comprising NH₃, N₂O, NO₂ and/or H₂O₂ may be provided in one or more deposition cycles to improve film properties. In some embodiments the IGeZO film may comprise a mixture of one or more individual oxides, such as indium zinc oxide (IZO) and germanium zinc oxide (GeZO). The various oxides can be used to tune the IGeZO film to achieve a desired result. In some embodiments a post-deposition anneal and/or a post deposition treatment may be carried out, for example to improve the electrical properties of the film. A post-deposition anneal may comprise, for example, annealing in an oxygen environment. The disclosed methods can enable high conformality and full stoichiometry control of IGeZO thin films, for example on high aspect ratio 3D structures, as needed for some memory applications.

In some embodiments, the indium germanium zinc oxide deposited by the disclosed methods can be used as the channel material in a transistor. This can allow for extremely low off currents and higher carrier mobility as compared to silicon. in some embodiments IGeZO is deposited at low temperatures (<200° C.) allowing its use in back end of line (BEOL) devices. In some embodiments the IGeZO film serves as a channel region in a BEOL logic device. In some embodiments the IGeZ0 thin films can be deposited on three-dimensional structures with high conformality and high uniformity. This can allow for the use of the IGeZO films in high aspect ratio devices such as DRAM, In some embodiments the IGeZO film serves as a DRAM access transistor channel. In some embodiments the IGeZO film serves as a VNAND (vertical NAND) channel.

Other contexts in which IGeZO thin films may be utilized will be apparent to the skilled artisan. In some embodiments the IGeZO thin films are not used in display technology. For example, in some embodiments the films are not used as a transparent film transistors (TFT) for use in a display.

As noted above, vapor deposition processes are provided for depositing IGeZO thin films. In some embodiments, atomic layer deposition (ALD) techniques are to deposit conformal IGeZO thin films. Among vapor deposition techniques, ALD has the advantage of providing high conformality at low temperatures. In some embodiments cyclic CVD process may be utilized. Thus, in some embodiments reaction temperatures may be above the decomposition temperature of at least one precursor. In cyclic CVD reactions at least partial mixing of one or more precursors and reactants may take place. For example, the ALD processes described below could be modified to provide the precursors and reactants simultaneously or in at least partially overlapping pulses in each sub-cycle.

ALD-type processes are based on controlled, generally self-limiting surface reactions of precursor chemicals. Gas phase reactions may be avoided by feeding the precursors alternately and sequentially into the reaction chamber. Vapor phase reactants are typically separated from each other in the reaction chamber, for example, by removing excess reactants and/or reactant by-products from the reaction chamber between reactant pulses.

Briefly, a substrate is loaded into a reaction chamber and is heated to a suitable deposition temperature, generally at lowered pressure. The substrate may be, for example, a semiconductor substrate. Deposition temperatures are maintained below the precursor thermal decomposition temperature but at a high enough level to avoid condensation of reactants and to provide the activation energy for the desired surface reactions. Of course, the appropriate temperature window for any given ALD reaction will depend upon the surface termination and reactant species involved.

In some embodiments the deposition temperature is from about 20° C. to about 600° C., from about to 100° C. to about 400° C., or from about 150° C. to about 300° C. In some embodiments the deposition temperature is about 225° C. or less. In some embodiments the deposition temperature is from about 150° C. to about 250° C. In some embodiments the deposition temperature is 225° C.

Each of the zinc, indium and germanium precursors is individually conducted into the chamber in the form of vapor phase pulse and contacted with the surface of a substrate. in some embodiments the substrate surface comprises a three dimensional structure. Conditions are selected such that no more than about one monolayer of each precursor is adsorbed on the substrate surface in a self-limiting manner.

One or more gaseous oxygen reactants are pulsed into the chamber where they react with the zinc, indium and/or germanium species on the surface to form a respective oxide.

Excess precursor or reactant and reaction byproducts, if any, may be removed from the substrate and substrate surface and from proximity to the substrate and substrate surface between pulses of each precursor or reactant. In some embodiments reactant and reaction byproducts, if any, may be removed by purging. Purging may be accomplished for example, with a pulse of inert gas such as nitrogen or argon.

Purging the reaction chamber means that vapor phase precursors or reactants and/or vapor phase byproducts are removed from the reaction chamber such as by evacuating the chamber with a vacuum pump and/or by replacing the gas inside the reactor with an inert gas such as argon or nitrogen. Typical purging times are from about 0.05 seconds to about 20 seconds, between about 1 second and about 10 seconds, or between about 1 second and about 2 seconds. However, other purge times can be utilized if necessary, such as when depositing layers over extremely high aspect ratio structures or other structures with complex surface morphology. The appropriate pulsing times can be readily determined by the skilled artisan based on the particular circumstances.

In other embodiments excess precursors (or reactants and/or reaction byproducts, etc.) are removed from the substrate surface or from the area of the substrate by physically moving the substrate from a location containing the precursor, reactant and/or reaction byproducts.

The steps of contacting the substrate with each precursor and reactant, such as by pulsing, and removing excess precursor or reactant and reaction byproducts are repeated until a thin IGeZO film of the desired thickness has been formed on the substrate, with each complete cycle typically leaving no more than about a molecular monolayer.

As mentioned above, each pulse or phase of each cycle is typically self-limiting. An excess of reactant precursors is supplied in each phase to saturate the susceptible structure surfaces. Surface saturation ensures reactant occupation of all available reactive sites (subject, for example, to physical size or “steric hindrance” restraints) and thus ensures excellent step coverage. In some arrangements, the degree of self-limiting behavior can be adjusted by, e.g., allowing some overlap of reactant pulses to trade off deposition speed (by allowing some CVD-type reactions) against conformality. Ideal ALD conditions with reactants well separated in time and space provide near perfect self-limiting behavior and thus maximum conformality, but steric hindrance results in less than one molecular layer per cycle. Limited CAD reactions mixed with the self-limiting ALD reactions can raise the deposition speed. As mentioned above, in some embodiments pulsed CND processes are used.

In some embodiments, a reaction space can be in a single-wafer ALD reactor or a batch ALD reactor where deposition on multiple substrates takes place at the same time. In some embodiments the substrate on which deposition is desired, such as a semiconductor workpiece, is loaded into a reactor. The reactor may be part of a cluster tool in which a variety of different processes in the formation of an integrated circuit are carried out. In some embodiments a flow-type reactor is utilized. In some embodiments a high-volume manufacturing-capable single wafer ALD reactor is used. In other embodiments a batch reactor comprising multiple substrates is used. For embodiments in which batch ALD reactors are used, the number of substrates is preferably in the range of 10 to 200, more preferably in the range of 50 to 150, and most preferably in the range of 100 to 130.

Examples of suitable reactors that may be used include commercially available ALD equipment. In addition to these ALD reactors, many other kinds of reactors capable of ALD growth of thin films, including CVD reactors equipped with appropriate equipment and means for pulsing the precursors can be employed. In some embodiments a flow type ALD reactor is used. Reactants are typically kept separate until reaching the reaction chamber, such that shared lines for the precursors are minimized. However, other arrangements are possible.

Suitable batch reactors include, but are not limited to, reactors designed specifically to enhance ALD processes. In some embodiments a vertical batch reactor is utilized in which the boat rotates during processing. Thus, in some embodiments the wafers rotate during processing. In some embodiments in which a batch reactor is used, wafer-to-wafer uniformity is less than 3% (lsigma), less than 2%, less than 1% or even less than 0.5%.

The IGeZO deposition processes described herein can optionally be carried out in a reactor or reaction space connected to a cluster tool. In a cluster tool, because each reaction space is dedicated to one type of process, the temperature of the reaction space in each module can be kept constant, which can improve the throughput compared to a reactor in which the substrate is heated up to the process temperature before each run.

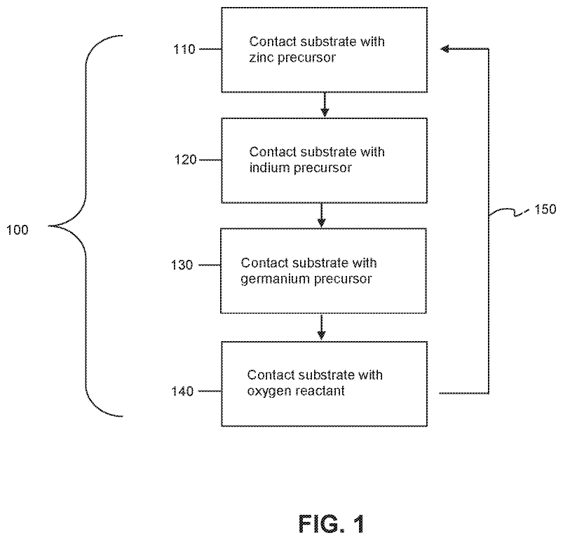

As illustrated in FIG. 1, in some embodiments, IGeZO thin films are deposited by an IGeZO deposition cycle 100 comprising alternately and sequentially contacting a substrate with a zinc precursor 110, an indium precursor 120, a germanium precursor 130 and an oxygen-containing reactant 140. The deposition cycle is repeated 150 to deposit an IGeZO film of the desired thickness.

In some embodiments the zinc precursor, indium precursor and germanium precursor are provided prior to the oxygen reactant. The zinc, indium and germanium precursors may be provided in any order. In some embodiments the substrate is contacted with the oxygen reactant after one or more of the zinc, indium and germanium precursors. In some embodiments the precursors are provided sequentially in a deposition cycle in which the substrate is alternately contacted with the zinc precursor, the indium precursor, the germanium precursor and the oxygen reactant, in that order. The deposition cycle is repeated to deposit an IGeZO film of the desired thickness. The deposition cycle may be written as [zinc precursor+indium precursor+germanium precursor+oxygen reactant]×N₁, where N is an integer and the brackets indicate one ALD cycle. The order of the zinc, indium and germanium precursors may vary. In some embodiments DEZ is used as a zinc precursor, TMIn is used as an indium precursor and an alkylamino germanium precursor, such as TDMAGe, is used as the germanium precursor and the deposition cycle may be written as [DEZ+TMIn+alkylamino germanium+oxygen reactant]×N1, where N is an integer and the brackets indicate one ALD cycle. Again, the order of the zinc, indium and germanium precursors may vary in some embodiments.

In some embodiments the oxygen reactant may be provided after one or more of the zinc, indium and germanium precursors, For example, in some embodiments an IGeZO deposition cycle (also referred to as a super-cycle) comprises three sub-cycles. In a first zinc oxide sub-cycle the substrate is alternately and sequentially contacted with the zinc precursor and an oxygen reactant. The first sub-cycle may be repeated one or more times. In a second indium oxide sub-cycle the substrate is alternately and sequentially contacted with an indium precursor and an oxygen reactant. The second sub-cycle may be repeated one or more times. In a third germanium oxide sub-cycle the substrate is alternately and sequentially contacted with a germanium precursor and an oxygen reactant. The third sub-cycle may be repeated one or more times. The oxygen reactant may be the same in each sub-cycle or may differ in one or more sub-cycles. Although referred to as the first, second and third sub-cycles, the sub-cycles may be carried out in any order in the super-cycle. In addition, the number of times that each sub-cycle is carried out may be independently varied in the super-cycle. For example, the number of times that one or more of the sub-cycles is carried out may be varied to achieve a desired composition. The number of times that each sub-cycle is carried out may be the same in each super-cycle or may vary. The super-cycle may be repeated one, two or more times to achieve a IGeZO film of the desired thickness and composition. The deposition super cycle comprising the three sub-cycles may be written as {[zinc precursor+oxygen reactant]×N2+[indium precursor+oxygen reactant]×N3+[germanium precursor+oxygen reactant]×N4}×N1, where N is an integer and the brackets represent one ALD sub-cycle. In some embodiments an anneal in an oxygen environment is included in the super cycle, and the deposition super cycle comprising the three sub-cycles may be written as {[zinc precursor+oxygen reactant]×N2[indium precursor+oxygen reactant]×N3+[germanium precursor+oxygen reactant]×N4+[oxygen reactant anneal]×N5}×N1, where N is an integer and the brackets represent one ALD sub-cycle. Such an oxygen reactant anneal step may be included in any of the deposition cycles described herein. In some embodiments DEZ is used as a zinc precursor, TMIn is used as an indium precursor and an alkylamino germanium precursor, such as TDMAGe, is used as a germanium precursor and the deposition super cycle comprising the three sub-cycles may be written as {[DEZ+oxygen reactant]×N2+[TMIn+oxygen reactant]×N3+[alkylamino germanium +oxygen reactant]×N4+[oxygen reactant anneal]×N5}×N1, where N is an integer and the brackets represent one ALD sub-cycle. In some embodiments DEZ is used as a zinc precursor, TMIn is used as an indium precursor and an alkylatnino germanium precursor, such as TDMAGe, is used as a germanium precursor.

In some embodiments one or more of the sub-cycles may be repeated multiple times relative to one or more other sub-cycles. For example, in some embodiments the indium oxide sub-cycle and the zinc oxide sub-cycle may be repeated a certain number of times relative to the germanium oxide sub-cycle. Such a super-cycle may be written as {[(zinc precursor+oxygen reactant)×N2+(indium precursor+oxygen reactant)×N3]×N4+[germanium precursor+oxygen reactant]×N5}+N1, where N is an integer and the brackets represent one ALD sub-cycle. In some embodiments DEZ is used as a zinc precursor, TMIn is used as an indium precursor and an alkylatnino germanium precursor, such as TDMAGe, is used as a germanium precursor.

In some embodiments an IGeZO deposition super-cycle comprises a first zinc indium oxide sub-cycle in which the substrate is alternately and sequentially contacted with a zinc precursor, an indium precursor and an oxygen reactant. The precursors may be provided in any order. The first sub-cycle may be repeated one or more times. In a second germanium oxide sub-cycle the substrate is alternately and sequentially contacted with a germanium precursor and an oxygen reactant. The second sub-cycle may be repeated one or more times. The oxygen reactant may be the same in each sub-cycle or may differ in one or more sub-cycles. Although referred to as the first and second sub-cycles, the sub-cycles may be carried out in any order in the super-cycle. In addition, the number of times that each sub-cycle is carried out may be independently varied in the super-cycle. For example, the number of times that one or more of the sub-cycles is carried out may be varied to achieve a desired composition. The number of times that each sub-cycle is carried out may be the same in each super-cycle or may vary. The super-cycle may be repeated one, two or more times to achieve a IGeZO film of the desired thickness and composition. The super-cycle comprising the two sub-cycles may be written as {[zinc precursor+indium precursor+oxygen reactant]×N2+[germanium precursor+oxygen reactant]×N3}×N1, where N is an integer and the brackets represent one ALD sub-cycle. In some embodiments DEZ is used as a zinc precursor, TMIn is used as an indium precursor and an alkylamino germanium compound such as TDMAGe is used as a germanium precursor and the deposition super cycle comprising the two sub-cycles may be written as {[DEZ+TMIn+oxygen reactant]×N2+[alkylamino germanium+oxygen reactant]×N3}×N1, where N is an integer and the brackets represent one ALD sub-cycle.

In some embodiments, an IGeZO deposition super-cycle comprises two sub-cycles in which in a first zinc germanium oxide sub-cycle the substrate is alternately and sequentially contacted with a zinc precursor, a germanium precursor and an oxygen reactant. The precursors may be provided in any order. The first sub-cycle may be repeated one or more times. In a second indium oxide sub-cycle, the substrate is alternately and sequentially contacted with an indium precursor and an oxygen reactant, The second sub-cycle may be repeated one or more times. The oxygen reactant may be the same in each sub-cycle or may differ in one or more sub-cycles, Although referred to as the first and second sub-cycles, the sub-cycles may be carried out in any order in the super-cycle, :In addition, the number of times that each sub-cycle is carried out may be independently varied in the super-cycle. For example, the number of times that one or more of the sub-cycles is carried out may be varied to achieve a desired composition. The number of times that each sub-cycle is carried out may be the same in each super-cycle or may vary. The super-cycle may be repeated one, two or more times to achieve a IGeZO film of the desired thickness and composition. The super-cycle comprising the two sub-cycles may be written as {[zinc precursor+germanium precursor+oxygen reactant]×N2+[indium precursor+oxygen reactant]×N3}+N1, where N is an integer and the brackets represent one ALD sub-cycle. In some embodiments DEZ is used as a zinc precursor, TMIn is used as an indium precursor and an alkylamino germanium compound such as TDMAGe is used as a germanium precursor and the deposition super cycle comprising the two sub-cycles may be written as {[DEZ+alkylamino germanium+oxygen reactant]×N2+[TMIn+oxygen reactant]×N3}×N1 where N is an integer and the brackets represent one ALD sub-cycle.

In some embodiments an IGeZO deposition super-cycle comprises two sub-cycles in which in a first zinc oxide sub-cycle the substrate is alternately and sequentially contacted with the zinc precursor and an oxygen reactant. The first sub-cycle may be repeated one or more times. In a second indium germanium oxide sub-cycle the substrate is alternately and sequentially contacted with an indium precursor, a germanium precursor and an oxygen reactant. The two precursors may be provided in any order. The second sub-cycle may be repeated one or more times. The oxygen reactant may be the same in each sub-cycle or may differ in one or more sub-cycles. Although referred to as the first and second sub-cycles, the sub-cycles may be carried out in any order in the super-cycle. In addition, the number of times that each sub-cycle is carried out may be independently varied in the super-cycle. For example, the number of times that one or more of the sub-cycles is carried. out may be varied to achieve a desired composition. The number of times that each sub-cycle is carried out may be the same in each super-cycle or may vary. The super-cycle may be repeated one, two or more times to achieve a IGeZO film of the desired thickness and composition. The super-cycle comprising the two sub-cycles may be written as {[zinc precursor+oxygen reactant]×N2+[indium precursor germanium precursor oxygen reactant]×N3}×N1, where N is an integer, and the brackets represent one AID sub-cycle. In some embodiments DEZ is used as a zinc precursor, TMIn is used as an indium precursor and an alkylamino germanium compound such as TDMAGe is used as a germanium precursor and the deposition super cycle comprising the two sub-cycles may be written as {[DEZ+oxygen reactant]×N2+[TMIn+alkylatnino germanium+oxygen reactant]×N3}×N1,where N is an integer, and the brackets represent one ALD sub-cycle.

In some embodiments a deposition super-cycle for producing a IGeZO film comprises one or more indium zinc oxide (IZO) sub-cycles and one or more germanium zinc oxide (GeZO) sub-cycles. In the IZO sub-cycle the substrate is alternately and. sequentially contacted with an indium precursor, a zinc precursor and an oxygen reactant. The indium and zinc precursors may be provided in any order. The IZO sub-cycle may be repeated one or more times. In the GeZ0 sub-cycle the substrate is alternately and sequentially contacted with a germanium precursor, a zinc precursor and an oxygen reactant. The germanium and zinc precursors may be provided in any order. The GeZO sub-cycle may be repeated one or more times. The oxygen reactant may be the same in each sub-cycle or may differ in one or more sub-cycles. The IZO and GeZ(I) sub-cycles may be carried out in any order in the super-cycle. In addition, the number of times that each sub-cycle is carried out may be independently varied in the super-cycle, for example to achieve a desired stoichiometry. For example, the number of times that the GeZO sub-cycle is carried relative to the IZO sub-cycle may be selected to achieve a desired In/Ge ratio in the IGeZO film. The super-cycle may be repeated one, two or more times to achieve a IGeZO film of the desired thickness and composition. The super-cycle comprising the two sub-cycles may be written as {[indium precursor+zinc precursor+oxygen reactant]×N2+[germanium precursor+zinc precursor+oxygen reactant]×N3}×N1, where N is an integer, and the brackets represent one ALD sub-cycle. In some embodiments DEZ is used as a zinc precursor, TMIn is used as an indium precursor and an alkylamino germanium precursor such as TDMAGe is used as a germanium precursor and the deposition super cycle comprising the two sub-cycles may be written as {[TMIn+DEZ+oxygen reactant]×N2+[alkylamino germanium+DEZ+oxygen reactant]×N3}×N1, where N is an integer, and the brackets represent one ALD sub-cycle.

In some embodiments a deposition super-cycle for producing a film with the desired properties comprises one or more indium zinc oxide (IZO) sub-cycles and one or more indium germanium zinc oxide (IGeZO) sub-cycles. The IZO sub-cycles and the IGeZO sub-cycles may be repeated at a selected ratio to produce a film with the desired properties. In the IZO sub-cycle the substrate is, for example, alternately and sequentially contacted with an indium precursor, a zinc precursor and an oxygen reactant, The indium and zinc precursors may be provided in any order, and an oxygen reactant may be provided after one or both precursors. The IZO sub-cycle may be repeated one or more times. The IGeZO may be formed by any of the deposition cycles described herein. In the IGeZO sub-cycle the substrate is alternately and sequentially contacted with an indium precursor, a germanium precursor, a zinc precursor and an oxygen reactant, as described herein. The indium, germanium and zinc precursors may be provided in any order, and an oxygen reactant may be provided after one or more of each of the precursors. The IGeZ( )sub-cycle may be repeated one or more times and, as mentioned above is conducted at a desired ratio with the WO sub-cycle. The oxygen reactant may be the same in each sub-cycle or may differ in one or more sub-cycles. The IZO and IGeZO sub-cycles may be carried out in any order in the super-cycle. In addition, the number of times that each sub-cycle is carried out may be independently varied in the super-cycle, for example to achieve a desired stoichiometry. For example, the number of times that the IGeZO sub-cycle is carried relative to the IZO sub-cycle may be selected to achieve a desired film. The super-cycle may be repeated one, two or more times to achieve a film of the desired thickness and composition. The super-cycle comprising the two sub-cycles may be written as {[IZO]×N2+[IGeZO]×N3}×N1, where N is an integer, and the brackets represent one ALD sub-cycle. In some embodiments DEZ is used as a zinc precursor, TMIn is used as an indium precursor and an alkylamino germanium precursor such as TDMAGe is used as a germanium precursor. In some embodiments a bilayer is formed comprising an IZO layer and an IGeZO layer.

As mentioned above, in some embodiments the IGeZO film may comprise a mixture of one or more individual oxides, such as indium zinc oxide (IZO) and germanium zinc oxide (GeZO) or IZO and IGeZo. In some embodiments the stoichiometry of an IGeZO film may be tuned by adjusting the ration of individual oxides in the film. In some embodiments a desired stoichiometry of an IGeZO film is achieved by selecting the numbers of each sub-cycle within a super-cycle, for example to provide a desired In/Ge ratio. In some embodiments one or more indium zinc oxide (IZO) and/or germanium zinc oxide (GeZO) sub-cycles may be included in a deposition process to arrive at a desired indium and germanium content in a film, such as a desired In/Ge ratio.

In some embodiments an additional reactant is included in one or more super-cycles. The additional reactant may, for example, improve the desired electrical properties of the IGeZO film. In some embodiments the additional reactant may be used to control the carrier density or concentration. In some embodiments the additional reactant may be used to control defect formation during growth of IGeZO layers. In some embodiments the additional reactant may passivate oxygen vacancies in the growing IGeZO film. In some embodiments the additional reactant may comprise one or more of NH₃, N₂O, NO₂ and H₂O₂.

In some embodiments the additional reactant is included in one or more sub-cycles in a super-cycle. in some embodiments the additional reactant is included in each sub-cycle in at least one super-cycle. In some embodiments the additional reactant is provided separately in at least one super-cycle, for example after completing one sub-cycle and before beginning the next.

In each of the sub-cycles described above, the additional reactant may be provide with or after the oxygen reactant. In some embodiments, the additional reactant may be provided alternately and sequentially after the oxygen reactant, For example, a sub-cycle including the additional reactant may be written as [metal precursor (zinc, indium or germanium)+oxygen reactant+additional reactant]×N1, where N is an integer. In some embodiments, the additional reactant may be provided with the oxygen reactant, as in the sequence: [metal precursor (zinc, indium or germanium)+(oxygen reactant+additional reactant)]×N1, where N is an integer. That is, in some embodiments the additional reactant is provided simultaneously with the oxygen reactant. In some embodiments the additional reactant may be flowed constantly throughout a deposition sub-cycle, or even throughout a deposition super-cycle.

In some embodiments the additional reactant is provided in one or more binary oxide sub-cycles. In some embodiments the additional reactant is provided in a zinc oxide sub-cycle, For example, a zinc oxide sub-cycle may be written as [zinc precursor+oxygen reactant ×additional reactant]×N1, where N is an integer. In some embodiments the additional reactant is provided in an indium oxide sub-cycle. For example, an indium oxide sub-cycle may be written as [indium precursor+oxygen reactant+additional reactant]×N1, where N is an integer. In some embodiments the additional reactant is provided in a germanium oxide sub-cycle. For example, a zinc oxide sub-cycle may be written as [germanium precursor+oxygen reactant+additional reactant]×N1, where N is an integer. As mentioned above, in some embodiments the additional reactant may be provide simultaneously with the oxygen reactant.

In some embodiments the additional reactant may be provided in an IZO and/or GeZO sub-cycle, Such an IZO sub-cycle may be given as, for example, [indium precursor+zinc precursor+oxygen reactant+additional reactant]×N where N is an integer. Such a IGeZO sub-cycle may be given as, for example, [germanium precursor+zinc precursor+oxygen reactant+additional reactant]×N where N is an integer. In some embodiments an IGeZO super-cycle may comprise an IZO sub-cycle and a GeZO sub-cycle that each use an additional reactant. This may be given as {[indium precursor+zinc precursor+oxygen reactant×additional reactant]×N2+[germanium precursor+zinc precursor+oxygen reactant+additional reactant]×N3}×N1, where N is an integer. As discussed above, the additional reactant may be provided simultaneously with the oxygen reactant in some embodiments. In some embodiments the additional reactant may flow throughout one or both of the sub-cycles, or even throughout the super-cycle.

In some embodiments the indium precursor comprises trimethyl indium (TMIn). In some embodiments the indium precursor comprises (3-dimethylaminopropyI)-dimethylindium. In some embodiments the indium precursor comprises In(acac). In some embodiments the indium precursor comprises InCp. In some embodiments the indium precursor comprises an indium halide, such as InCl₃. In some embodiments the indium compound may be a metal-organic or organometallic In-compound, such as an In compound with a direct bond to from In to a ligand comprising an organic part or a direct In-C bond.

In some embodiments the germanium precursor comprises an germanium amine or akylyamino compound. In some embodiments the germanium compound is tetrakis(dimethylamino)germanium (Ge(NMe₂)₃; TDMAGe). in some embodiments the compound is tetrakis(di ethylaminogermanium (Ge(NEt₂)₃; TDEAGe), In some embodiments the germanium compound is or tetrakis(ethylmethylamino) germanium (Ge(NEtMe)₃, TEMAGe). In some embodiments the germanium compound may be a metal-organic or organometallic germanium compound, such as a germanium compound having a direct bond to from Ge to a ligand comprising an organic part or a direct Ge-C bond.

In some embodiments the germanium compound may be an alkoxide. For example, in some embodiments the germanium precursor is selected from germanium ethoxide (GeOEt)₄. Other possible germanium precursors are provided below and may include germanium compounds containing Ge-O bonds, Ge-C bonds (for example, germanium alkyls), or Ge-N bonds (for example, germanium alkylamines). In some embodiments, the Ge precursor contains a halide in at least one ligand, but not in all ligands.

Ge precursors from formulas (1) through (9) below may be used in some embodiments.

(1) GeOR₄

Wherein R is can be independently selected from the group consisting of alkyl and substituted alkyl;

(2) GeRₓA₄₋ₓ

Wherein the x is an integer from 1 to 4;

R is an organic ligand and can be independently selected from the group consisting of alkoxides, alkylsilyls, alkyl, substituted alkyl, alkylamines; and

A can be independently selected from the group consisting of alkyl, substituted alkyl, alkoxides, alkylsilyls, alkyl, alkylamines, halide, and hydrogen.

(3) Ge(OR)×A₄₋ₓ

Wherein the x is an integer from 1 to 4;

R can be independently selected from the group consisting of alkyl and substituted alkyl; and

A can be independently selected from the group consisting of alkyl, alkoxides, alkylsilyls, alkyl, substituted alkyl, alkylamines, halide, and hydrogen.

(4) Ge(NR^{I}R^{II})₄

Wherein R^{I} can be independently selected from the group consisting of hydrogen, alkyl and substituted alkyl; and

R^{II} can be independently selected from the group consisting of alkyl and substituted alkyl;

(5) Ge(NR^{I}R^{II})ₓA₄₋ₓ

Wherein the x is an integer from 1 to 4;

R^{I} can be independently selected from the group consisting of hydrogen, alkyl and substituted alkyl; and

R^{II} can be independently selected from the group consisting of alkyl and substituted alkyl;

A can be independently selected from the group consisting of alkyl, alkoxides, alkylsilyls, alkyl, substituted alkyl, alkylamines, halide, and hydrogen.

(6) Geₙ(NR^{I}R^{II})₂ₙ₊₂

Wherein the n is an integer from 1 to 3;

R^{I} can be independently selected from the group consisting of hydrogen, alkyl and substituted alkyl; and

R^{II} can be independently selected from the group consisting of alkyl and substituted alkyl;

(7) Gen(OR)₂ₙ₊₂

Wherein the n is an integer from 1 to 3; and

Wherein R can be independently selected from the group consisting of alkyl and substituted alkyl;

(8) GeₙR₂ₙ₊₂

Wherein the n is an integer from 1 to 3; and

R is an organic ligand and can be independently selected from the group consisting of alkoxides, alkylsilyls, alkyl, substituted alkyl, alkylamines.

(9) A₃₋ₓRₓGe—GeR_{y}A_{3-y}

Wherein the x is an integer from 1 to 3;

y is an integer from 1 to 3;

R is an organic ligand and can be independently selected from the group consisting of alkoxides, alkylsilyls, alkyl, substituted alkyl, alkylamines; and

A can be independently selected from the group consisting of alkyl, alkoxides, alkylsilyls, alkyl, substituted alkyl, alkylamines, halide, and hydrogen.

Preferred options for R include, but are not limited to, methyl, ethyl, propyl, isopropyl, n-butyl, isobutyl, tertbutyl for all formulas, more preferred in ethyl and methyl. In some embodiments, the preferred options for R include, but are not limited to, C₃-C₁₀ alkyls, alkenyls, and alkynyls and substituted versions of those, more preferably C₃-C₆ alkyls, alkenyls, and alkenyls and substituted versions of those.

In some embodiments the Ge precursor comprises one or more halides, For example, the precursor may comprise 1, 2, or 3 halide ligands.

In some embodiments alkoxide Ge precursors may be used, including, but are not limited to, one or more of Ge(OMe)₄, Ge(OEt)₄, Ge(OⁱPr)₄, Ge(OⁿPr)₄ and Ge(O^{t}Bu)₄. In some embodiments the Ge precursor is TDMAGe. In some embodiments the Ge precursor is TDEAGe. In some embodiments the Ge precursor is TEMAGe.

In some embodiments the zinc precursor comprises one or more of elemental Zn, Zn halides, such as ZnCl₂, and alkyl zinc compounds such Zn(Et)₂ or Zn(Me). In some embodiments the zinc precursor is diethyl zinc (DEZ). In some embodiments the zinc compound may be a metal-organic or organometallic Zn-compound, such as one having a direct bond to from Zn to a ligand comprising an organic part or a direct Zn—C bond.

In some embodiments the oxygen reactant comprises one or more of water, ozone, H₂O₂, oxygen atoms, oxygen radicals, oxygen plasma, NO₂, N₂0 and other compounds comprising N and O, but not metals or semimetals. In some embodiments the oxygen reactant is water. In some embodiments the oxygen reactant is N₂O. In some embodiments, such as described above, one or more oxygen reactants are used in the deposition processes to react with one or more indium, zinc or germanium precursors to form the respective oxides. For example, the oxygen reactant may be used in a in binary oxide sub-cycle with one of an indium, zinc or germanium precursor, or in a multicomponent oxide sub-cycle, such as a sub-cycle that forms IZO, GeZO or IGeZO, for example, for tuning the stoichiometry or composition or desired properties of the films.

The zinc, indium and germanium precursors employed in the ALD type processes may be solid, liquid, or gaseous material under standard conditions (room temperature and atmospheric pressure), provided that the precursors are in vapor phase before being conducted into the reaction chamber and contacted with the substrate surface. In some embodiments diethyl zinc (DEZ) is used as the zinc source and is heated up to about 40° C. In some embodiments trimethyl indium (TMIn) is used as an indum source and is heated up to about 40° C. In some embodiments DEZ and/or TMIn are used at room temperature. In some embodiments TMAGe is used as the germanium source and is heated to above about 70° C.

“Pulsing” a vaporized precursor onto the substrate means that the precursor vapor is conducted into the chamber for a limited period of time. Depending on the specific process, the pulsing time is from about 0.05 seconds to about 10 seconds. However, depending on the substrate type and its surface area, the pulsing time may be even higher than about 10 seconds. In some embodiments the pulsing time may be from about 0.05 seconds to about 60 seconds or even up to about 120 seconds, such as in a batch approach.

For example, for a 300 mm wafer in a single wafer ALD reactor, the zinc, indium or germanium precursor may be pulsed for from about 0.05 seconds to about 10 seconds, for from about 0.1 seconds to about 5 seconds or for from about 0.3 seconds to about3.0 seconds. The oxygen-containing precursor may be pulsed, for example, for from about 0.05 seconds to about 10 seconds, for from about 0.1 seconds to about 5 seconds, or for from about 0.2 seconds to about 3.0 seconds. However, pulsing times can be on the order of minutes in some cases. The optimum pulsing time can be readily determined by the skilled artisan based on the particular circumstances.

Before starting the deposition of the film, the substrate is typically heated to a suitable growth temperature, as discussed above. The deposition temperature may vary depending on a number of factors such as, and without limitation, the reactant precursors, the pressure, flow rate, the arrangement of the reactor, and the composition of the substrate including the nature of the material to be deposited on.

In some embodiments an IGeZO film is deposited to a thickness of 200 nm or less, about 100 nm or less, about 50 nm or less, about 30 nm or less, about 20 nm or less, about 10 nm or less, about 5 nm or less or about 3 nm or less. The IGeZO film will comprise at least the material deposited in one deposition cycle.

Atomic layer deposition allows for conformal deposition of IGeZO films. In some embodiments, the IGeZO films deposited by the processes disclosed herein on a three-dimensional structure have at least 90%, 95% or higher confonnality. In some embodiments the films are about 100% conformal.

In some embodiments, the TZGeO film formed has step coverage of more than about 80%, more than about 90%, and more than about 95% in structures which have high aspect ratios. In some embodiments high aspect ratio structures have an aspect ratio that is more than about 3:1 when comparing the depth or height to the width of the feature. In some embodiments the structures have an aspect ratio of more than about 5:1, an aspect ratio of 10:1, an aspect ratio of 20:1, an aspect ratio of 40:1, an aspect ratio of 60:1,an aspect ratio of 80:1, an aspect ratio of 100:1, an aspect ratio of 150:1, an aspect ratio of 200:1 or greater.

In some embodiments, the IZGeO film formed has carbon impurities less than 20 at-%, less than 10 at-%, less than 5 at-%, less than 2 at-%, less than 1 at-% or less than 0.5 at-%. In some embodiments, the IZGeO film formed has hydrogen impurities less than 30 at-%, less than 20 at-%, less than 10 at-%, less than 5 at-%, less than 3 at-% or less than 1 at-%.

In some embodiments, the IZGeO film formed has stoichiometry or elemental ratio (In:Ge:Zn) of about 1:1:1, or from 0.1:1:1 to 10:1:1, or from 1:0.1:1 to 1:10:1, or from 1:1:0.1 to 1:1:10, or from 0.1:0.1:1 to 10:10:1, or from 0,1:1:0.1 to 10:1:10, or from 1:0.1:0.1 to 1:10:10. In some embodiments, the IZGeO film formed has stoichiometry or elemental ratio (In:Ge:Zn) from 0,01:1:1 to 100:1:1, or from 1:0,01:1 to 1:100:1, or from 1:1:0.01 to 1:1:100, or from 0.01:0.01:1 to 100:100:1, or from 0.01:1:0.01 to 100:1:100, or from 1:0.01:0.01 to 1:100:100. The same ratios can be achieved in GZO, IGO and IZO films, respectively (without the metal component that's not included).

In some embodiments, the IGeZO films deposited by processes disclosed herein are annealed after the deposition, as desired depending on the application. in some embodiments the IGeZO films are annealed in an oxygen environment. For example, the films may be annealed at an elevated temperature in water, O₂ or any of the other oxygen reactants mentioned above. In some embodiments the films may be annealed in an oxygen reactant comprising oxygen plasma, oxygen radicals, atomic oxygen or excited species of oxygen. In some embodiments the films are annealed in a hydrogen containing environment or in an inert atmosphere, such as a N₂, Ar or He atmosphere. In some embodiments an annealing step is not carried out.

In some embodiments, following IGeZO deposition, a further film is deposited. The additional film may be directly over and contacting the ALD-deposited IGeZO layer.

Although certain embodiments and examples have been discussed, it will be understood by those skilled in the art that the scope of the claims extend beyond the specifically disclosed embodiments to other alternative embodiments and/or uses and obvious modifications and equivalents thereof.

What is claimed is:

1. An atomic layer deposition (ALD) process for forming an indium germanium zinc oxide (IGeZO) channel layer in a transistor device, the ALD process comprising a deposition cycle comprising alternately and sequentially contacting a substrate in a reaction space with a vapor phase indium precursor, a vapor phase germanium precursor, a vapor phase zinc precursor and an oxygen reactant, and repeating the deposition cycle until an IGeZO thin film of the desired thickness has been formed.

2. The process of claim 1, wherein the deposition cycle additionally comprises contacting the substrate with an additional reactant comprising one or more of NH₃, N₂O, NO₂ and H₂O₂.

3. The process of claim 2, wherein the substrate is contacted simultaneously with the oxygen reactant and the additional reactant.

4. The process of claim 1, wherein the Ge precursor comprises at least one amine or alkylamine ligand.

5. The process of claim 1, wherein the zinc precursor comprises one or more of elemental Zn, a Zn halide, and an alkyl zinc compound.

6. The process of claim 1, wherein the indium precursor comprises one or more of trimethyl indium, In(acac), InCp, and an indium halide.

7. The process of claim 1, wherein the indium precursor is trimethyl indium, the zinc precursor is diethyl zinc and the germanium precursor is TDMAGe.

8. The process of claim 1, wherein the deposition cycle is conducted at a deposition temperature of 250° C. or less.

9. The process of claim 1, wherein in the deposition cycle the substrate is contacted with the oxygen reactant after being contacted with the indium, zinc and germanium precursors.

10. The process of claim 1, wherein the deposition cycle comprises an indium zinc oxide sub-cycle and a germanium zinc oxide sub-cycle and the IGeZO film comprises a mixture of indium zinc oxide and germanium zinc oxide.

11. The process of claim 1, wherein the deposition cycle is repeated N1 times and comprises a zinc oxide sub-cycle that is repeated N2 times, the zinc oxide sub-cycle comprising alternately and sequentially contacting the substrate with the zinc precursor and the oxygen reactant, an indium oxide sub-cycle that is repeated N3 times, the indium oxide sub-cycle comprising alternately and sequentially contacting the substrate with the indium precursor and the oxygen reactant and a germanium oxide sub-cycle that is repeated N4 times, the germanium oxide sub-cycle comprising alternately and sequentially contacting the substrate with the germanium precursor and the oxygen reactant, wherein N is an integer.

12. The process of claim 1, wherein the deposition cycle is repeated N1 times and comprises a zinc indium oxide sub-cycle that is repeated N2 times and comprises alternately and sequentially contacting the substrate with the zinc precursor, the indium precursor and the oxygen reactant and a germanium oxide sub-cycle that is repeated N3 times and comprises alternately and sequentially contacting the substrate with the germanium precursor and the oxygen reactant, where N is an integer.

13. The process of claim 1, wherein the deposition cycle is repeated N1 times and comprises a zinc germanium oxide sub-cycle that is repeated N2 times and comprises alternately and sequentially contacting the substrate with the zinc precursor, the germanium precursor and the oxygen reactant; and an indium oxide sub-cycle that is repeated N3 times and comprises alternately and sequentially contacting the substrate with the indium precursor and the oxygen reactant, where N is an integer.

14. The process of claim 1, wherein the deposition cycle is repeated N1 times and comprises a zinc oxide sub-cycle that is repeated N2 times and comprises alternately and sequentially contacting the substrate with the zinc precursor and the oxygen reactant; and an indium germanium oxide sub-cycle that is repeated N3 times and comprises alternately and sequentially contacting the substrate with the indium precursor and the germanium precursor and the oxygen reactant, where N is an integer.

15. The process of claim 1, wherein the deposition cycle is repeated N1 times and comprises an indium zinc oxide (IZO) sub-cycle that is repeated. N2 times and an indium germanium oxide (IGeZO) sub-cycle that is repeated N3 times, where N is an integer.

16. The process of claim 21, wherein the IZO and IGeZO sub-cycles are carried out at a preselected ratio.

17. An atomic layer deposition (ALD) process for forming an indium germanium zinc oxide (IGeZO) thin film on a substrate in a reaction space comprising:
conducting a deposition cycle comprising contacting the substrate with a vapor phase indium precursor, a vapor phase germanium precursor, a vapor phase zinc precursor, a first oxygen reactant, and a second reactant; and
repeating the deposition cycle two or more until a IGeZO thin film of the desired thickness has been formed, wherein the second reactant comprises one or more of NH₃, N₂O, NO₂ and H₂O₂.

18. The process of claim 17, wherein the substrate is contacted with the first oxygen reactant after being contacted with one or more of the indium germanium and zinc reactants.

19. The process of claim 17, wherein the substrate is contacted with the first oxygen reactant and the second reactant simultaneously,

20. The process of claim 19, wherein the second reactant is provided to the reaction space continuously during the deposition cycle.
